(19) United States
(12) Patent Application Publication
(10) Pub. No.: US 2021/0013169 A1
(43) Pub. Date: Jan. 14, 2021

(54) DISPLAY PANEL AND MANUFACTURING METHOD OF THE DISPLAY PANEL

(71) Applicant: SAKAI DISPLAY PRODUCTS CORPORATION, Osaka (JP)

(72) Inventor: SHINICHI SUGIMOTO, Osaka (JP)

(21) Appl. No.: 16/923,766

(22) Filed: Jul. 8, 2020

Related U.S. Application Data
(60) Provisional application No. 62/873,436, filed on Jul. 12, 2019.

(51) Int. Cl. H01L 23/00; G02F 1/1345

(52) U.S. Cl. CPC H01L 24/32; G02F 1/13452; H01L 24/83; H01L 2224/32227; H01L 2224/2929; H01L 2224/83862; H01L 2224/29311; H01L 2224/2949; H01L 2224/83851; H01L 2224/83874; H01L 2224/29309

(57) ABSTRACT

A display panel is manufactured that includes a first panel substrate, a second panel substrate that is opposite the first panel substrate and has a protruding portion protruding from the first panel substrate, and a wiring board connected to the protruding portion of the second panel substrate. A manufacturing method of the display panel includes: overlapping protruding terminals and wiring terminals with the protruding terminals and the wiring terminals being opposite each other through an anisotropic conductive film; exposing the conductive layer on a surface of particles, located between the protruding terminals and the wiring terminals that are opposite each other, of the particles in the anisotropic conductive film; and curing the curable resin layer of particles, located in regions between the protruding terminals or regions between the wiring terminals when viewed in a normal direction of the second panel substrate, of the particles in the anisotropic conductive film.

### INCORPORATION BY REFERENCE

The present application claims benefit of priority to U.S. Provisional Patent Application No. 62/873,436, filed on Jul. 12, 2019. The contents of this application are incorporated herein by reference in its entirety.

### BACKGROUND

The present disclosure relates to a display panel and a manufacturing method of the display panel.

Flat-panel types of display panels have widely spread. A display panel includes a panel body including pixels and a drive circuit that is externally attached to the panel body and that drives the panel body. Signals for driving the pixels of the panel body are transmitted from the drive circuit to the panel body.

As an example of the display panel, there is a known display panel in which a driver IC and a drive circuit board are mounted on a flexible wiring board. In this type of display panel, the wiring board is bonded to a connection portion of a thin film transistor (TFT) substrate of the panel body through an anisotropic conductive film.

In recent years, further miniaturization and/or high definition of display panels have been demanded, and it has been studied to further reduce a pitch between wires of the wiring board and a pitch between terminals of a protruding portion of the TFT substrate. Leaks may however occur between wires and/or terminals in a general display panel in which a wiring board is bonded to a TFT substrate through an anisotropic conductive film.

### SUMMARY

A manufacturing method of a display panel, of the present embodiment manufactures a display panel that includes a first panel substrate; a second panel substrate that is opposite the first panel substrate and that has a protruding portion that protrudes from the first panel substrate; and a wiring board connected to the protruding portion of the second panel substrate. The manufacturing method of the display panel includes: overlapping protruding terminals and wiring terminals with the protruding terminals and the wiring terminals being opposite each other through an anisotropic conductive film, the protruding terminals being provided at the protruding portion, the wiring terminals being placed on one surface of the wiring board, the anisotropic conductive film containing particles having a conductive layer and a curable resin layer covering a surface of the conductive layer; exposing the conductive layer on a surface of particles, located between the protruding terminals of the second panel substrate and the wiring terminals of the wiring board that are opposite each other, of the particles in the anisotropic conductive film; and curing the curable resin layer of particles, located in regions between the protruding terminals of the second panel substrate or regions between the wiring terminals of the wiring board when viewed in a normal direction of the second panel substrate, of the particles in the anisotropic conductive film.

A display panel of the present embodiment includes a first panel substrate, a second panel substrate that is opposite the first panel substrate, a wiring board, and an anisotropic conductive film. The second panel substrate has a protruding portion that protrudes from the first panel substrate. The wiring board is connected to the protruding portion of the second panel substrate. Protruding terminals are provided at the protruding portion. The wiring board has one surface on which the wiring terminals are placed. The protruding terminals of the protruding portion in the second panel substrate and the wiring terminals on the one surface of the wiring board are overlapped through the anisotropic conductive film with the protruding terminals and the wiring terminals being opposite each other. The anisotropic conductive film contains base resin and particles dispersed in the base resin. The particles have a conductive layer, and a curable resin layer covering the conductive layer. Particles, located between the protruding terminals of the second panel substrate and the wiring terminals of the wiring board that are opposite each other, of the particles in the anisotropic conductive film have a surface formed as a result of the conductive layer being exposed. The curable resin layer of particles, located in regions between the protruding terminals of the second panel substrate or regions between the wiring terminals of the wiring board when viewed in a normal direction of the second panel substrate, of the particles in the anisotropic conductive film is cured.

### BRIEF DESCRIPTION OF THE DRAWINGS

FIG. 1 is a schematic illustration of a display panel according to a first embodiment.

FIG. 2A is an enlarged view of a part, in the vicinity of a COF, of the display panel according to the first embodiment.

FIG. 2B is a schematic side view of the part in the vicinity of the COF in FIG. 2A.

FIG. 3 is an enlarged view of a part of a layered structure of a TFT substrate, an anisotropic conductive film, and a COF in the display panel according to the first embodiment.

FIG. 4A is a schematic illustration depicting a manufacturing method of the display panel, according to the first embodiment.

FIG. 4B is a schematic illustration depicting the manufacturing method of the display panel, according to the first embodiment.

FIG. 4C is a schematic illustration depicting the manufacturing method of the display panel, according to the first embodiment.

FIG. 5A is a schematic illustration depicting a change in the vicinity of the COF by a manufacturing method of the display panel, according to the first embodiment.

FIG. 5B is a schematic illustration depicting a change in the vicinity of the COF by the manufacturing method of the display panel, according to the first embodiment.

FIG. 5C is a schematic illustration depicting a change in the vicinity of the COF by the manufacturing method of the display panel, according to the first embodiment.

FIG. 6A is a schematic illustration of a particle used for the manufacturing method of the display panel, according to the first embodiment.

FIG. 6B is a schematic illustration of a particle used for the manufacturing method of the display panel, according to the first embodiment.

FIG. 7A is a schematic illustration depicting a change in the vicinity of the COF by a manufacturing method of the display panel, according to the first embodiment.

FIG. 7B is a schematic illustration depicting a change in the vicinity of the COF by the manufacturing method of the display panel, according to the first embodiment.

FIG. 7C is a schematic illustration depicting a change in the vicinity of the COF by the manufacturing method of the display panel, according to the first embodiment.

FIG. 8A is a schematic illustration depicting a change in the vicinity of the COF by a manufacturing method of the display panel, according to the first embodiment.

FIG. 8B is a schematic illustration depicting a change in the vicinity of the COF by the manufacturing method of the display panel, according to the first embodiment.

FIG. 8C is a schematic illustration depicting a change in the vicinity of the COF by the manufacturing method of the display panel, according to the first embodiment.

FIG. 9 is an enlarged view of a part of a layered structure of a TFT substrate, an anisotropic conductive film, and a COF in a display panel according to a second embodiment.

FIG. 10 is an enlarged view of a part of a layered structure of a TFT substrate, an anisotropic conductive film, and a COF in a display panel according to a third embodiment.

FIG. 11 is an enlarged view of a part of a layered structure of a TFT substrate, an anisotropic conductive film, and a COF in a display panel according to a fourth embodiment.

### DETAILED DESCRIPTION

Embodiments of a display panel and a display panel manufacturing method according to the present disclosure will hereinafter be described with reference to the drawings. The present disclosure is however not limited to the embodiments below. In the specification of the present application, mutually perpendicular X, Y, and Z directions may be indicated in order to facilitate understanding of the disclosure. Typically, the X and Y directions are parallel to a horizontal direction, and the Z direction is parallel to a vertical direction.

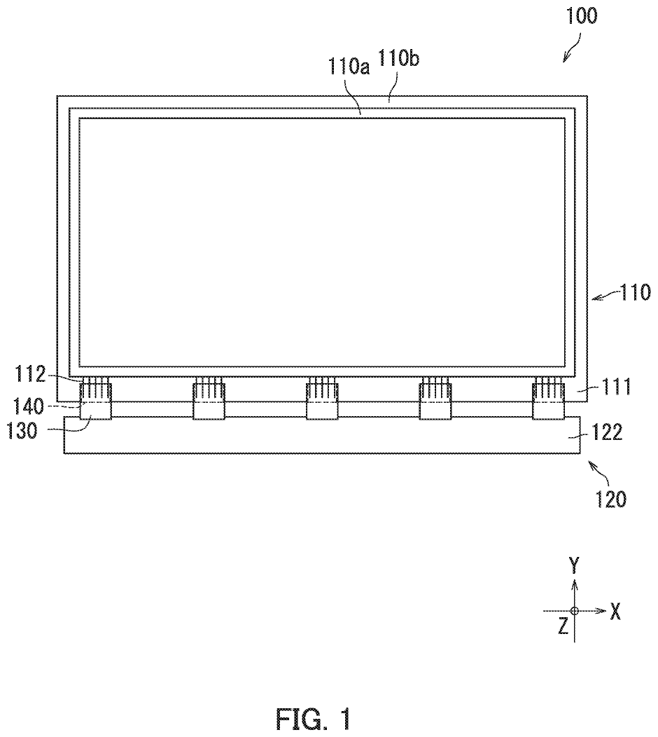

A display panel 100 of a first embodiment will be described with reference to FIG. 1. FIG. 1 is a schematic illustration of the display panel 100 of the first embodiment. Here, a normal direction of a main surface of the display panel 100 is in the Z direction.

The display panel 100 includes a panel body 110, a drive circuit section 120, and anisotropic conductive films 140. The panel body 110 displays an image. The drive circuit section 120 drives the panel body 110. Terminals 112 are provided at an end of the panel body 110. The terminals 112 are insulated from each other. The drive circuit section 120 is placed on one side of the panel body 110. The drive circuit section 120 is electrically connected with the terminals 112 of the panel body 110, and transmits signals to the panel body 110. Each terminal 112 is an example of a protruding terminal.

The anisotropic conductive films 140 electrically connect the panel body 110 and the drive circuit section 120. The anisotropic conductive films 140 cover the end of the panel body 110. The anisotropic conductive films 140 may extend to the outside of the panel body 110.

Here, the panel body 110 is rectangular in shape. A lengthwise direction of the panel body 110 is parallel to the X direction, and a widthwise direction of the panel body 110 is parallel to the Y direction.

For example, the panel body 110 is a liquid-crystal display panel. The panel body 110 includes a color filter substrate 110a and a TFT substrate 110b. The color filter substrate 110a is provided with a color filter. The TFT substrate 110b is provided with a thin film transistor (TFT) for each pixel. A liquid-crystal layer is placed between the color filter substrate 110a and the TFT substrate 110b. The color filter substrate 110a is stacked on the TFT substrate 110b. The color filter substrate 110a is an example of a first panel substrate. The TFT substrate 110b is an example of a second panel substrate.

Typically, the color filter substrate 110a includes a transparent substrate. The transparent substrate is made from glass or resin.

Typically, the TFT substrate 110b includes a transparent substrate. The transparent substrate is made from glass or resin.

The color filter substrate 110a and the TFT substrate 110b are opposite each other. A size of the TFT substrate 110b is larger than a size of the color filter substrate 110a. The TFT substrate 110b includes a protruding portion 111 that protrudes from the color filter substrate 110a. The terminals 112 are provided at the protruding portion 111 of the TFT substrate 110b. Each terminal 112 includes a conductive member. In one example, the terminals 112 are made of copper.

The drive circuit section 120 includes a printed board 122 and a chip on film (COF) 130. The COF 130 is shaped like a thin film. The panel body 110 is electrically connected with the printed board 122 through the COF 130. The COF 130 is pressure-bonded to the TFT substrate 110b. The COF 130 is connected to the protruding portion 111 of the TFT substrate 110b. The COF 130 preferably has flexibility.

Here, the printed board 122 is rectangular in shape. A lengthwise direction of the printed board 122 is parallel to the X direction, and a widthwise direction of the printed board 122 is parallel to the Y direction.

The COF 130 is placed at the end of the panel body 110. Specifically, the COF 130 is electrically connected with corresponding terminals 112 of the TFT substrate 110b of the panel body 110 through an anisotropic conductive film 140. Here, more than one COF 130 are provided for one printed board 122 and one panel body 110. A length of each COF 130 in the X direction is shorter than lengths of the panel body 110 and the printed board 122 in the X direction.

Each COF 130 is provided with wiring terminals on the substrate, and the wiring terminals of the COF 130 are electrically connected with a semiconductor chip mounted on the substrate. Each COF 130 is an example of a wiring board.

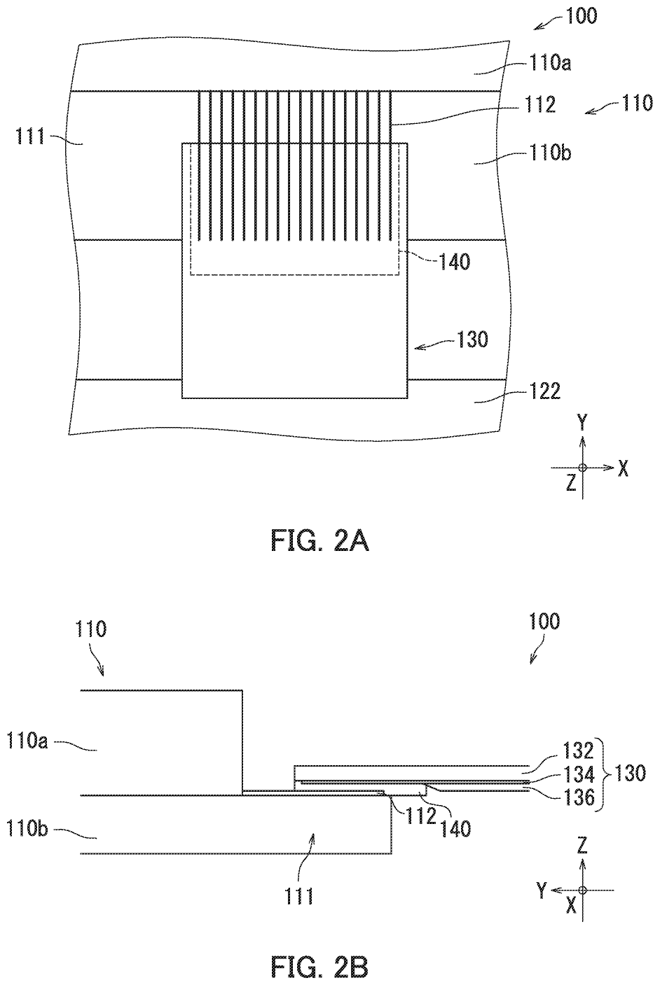

A structure, in the vicinity of a COF 130, of the display panel 100 of the first embodiment will next be described with reference to FIGS. 2A and 2B. FIG. 2A is an enlarged view of a part, in the vicinity of the COF 130, of the display panel 100 of the first embodiment, and FIG. 2B is a side view of the part in the vicinity of the COF 130 in FIG. 2A.

As described above, in the panel body 110, the size of the TFT substrate 110b is larger than the size of the color filter substrate 110a. Most part of a main surface of the TFT substrate 110b overlaps with the color filter substrate 110a, while the protruding portion 111 of the TFT substrate 110b protrudes from the color filter substrate 110a. The protruding portion 111 is provided with the terminals 112.

As described above, the COF 130 is shaped like a thin film. The COF 130 has two main surfaces. One surface of the COF 130 is one of the two main surfaces, and is opposite the TFT substrate 110b. In addition, the other surface of the COF 130 is the other of the two main surfaces.

The COF 130 includes a base substrate 132, wires 134, and an insulating layer 136. The wires 134 are placed on one main surface (one surface) of the base substrate 132. The wires 134 are insulated from each other. Here, the wires 134 are placed on the main surface of the base substrate 132 on the lower side (on a side of the TFT substrate 110b). The insulating layer 136 covers at least part of the wires 134 without covering part, overlapping with the terminals 112 of the TFT substrate 110b, of the wires 134. Here, the COF 130 has a single-sided mounting structure. The wires 134 are an example of the wiring terminals.

In an example, the base substrate 132 is made from polyimide resin. Alternatively, the base substrate 132 may be made from polyethylene terephthalate (PET) resin. Each wire 134 contains a conductive member. In one example, the wires 134 are made of copper. In an example, the insulating layer 136 is made from epoxy resin.

The anisotropic conductive film 140 bonds the TFT substrate 110b of the panel body 110 and the COF 130. The wires 134 placed on the one surface of the COF 130 and corresponding terminals 112 provided for the protruding portion 111 of the TFT substrate 110b of the panel body 110 are opposite through the anisotropic conductive film 140. In addition, the anisotropic conductive film 140 electrically connects the terminals 112 placed on the TFT substrate 110b of the panel body 110 and the wires 134 of the COF 130.

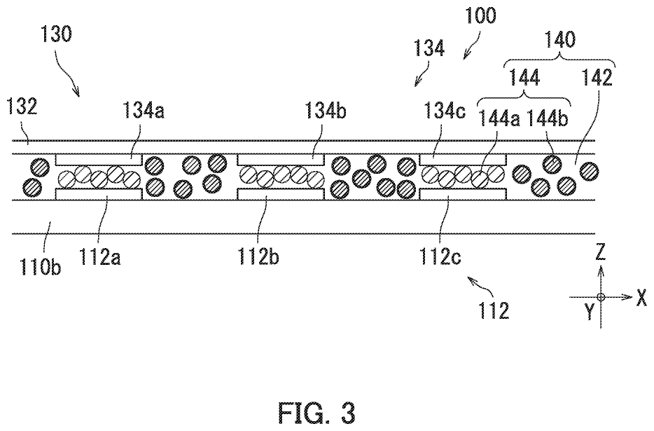

A layered structure of the TFT substrate 110b, an anisotropic conductive film 140, and a COF 130 in the display panel 100 in the first embodiment will next be described with reference to FIG. 3. FIG. 3 is a schematic illustration depicting the layered structure of the TFT substrate 110b, the anisotropic conductive film 140, and the COF 130 in the display panel 100 in the first embodiment.

As described above, the COF 130 is opposite the TFT substrate 110b through the anisotropic conductive film 140. In addition, the wires 134 of the COF 130 are opposite terminals 112 of the TFT substrate 110b. In FIG. 3, terminals 112a, 112b, and 112c are illustrated as the terminals 112, and wires 134a. 134b, and 134c are illustrated as the wires 134.

The anisotropic conductive film 140 includes base resin 142 and particles 144. The base resin 142 has adhesiveness. The base resin 142 enables bonding between the TFT substrate 110b and the COF 130.

The particles 144 are dispersed in the base resin 142. For example, the anisotropic conductive film 140 is 5 μm or more and 200 μm or less in thickness. For example, the particles 144 are 1 μm or more and 100 μm or less in average particle diameter.

Here, the pitch between the terminals 112 is almost equal to the pitch between the wires 134. For example, a distance between the terminal 112a and the terminal 112b is 3 μm or more and 200 μm or less. Similarly, a distance between the wire 134a and the wire 134b is 3 μm or more and 200 μm or less. Note that the distance between the terminals 112 or the distance between the wires 134 is preferably not less than 2 times and not more than 20 times the average particle diameter of the particles 144. Although the terminals 112 are almost equal in width to the wires 134 in the display panel 100 of the present embodiment, the terminals 112 may differ from the wires 134 in width. The distance between the terminals 112 may accordingly differ from the distance between the wires 134.

The particles 144 include particles 144a and particles 144b. At least each surface of the particles 144a exhibits conductivity. The particles 144b have at least a surface exhibiting insulation. The particles 144a and the particles 144b are dispersed in the base resin 142. Although details will be described later, the particles 144a and the particles 144b are formed from the same particles.

Particles 144a are located between the wires 134 of the COF 130 and terminals 112 of the TFT substrate 110b that are opposite each other, in the anisotropic conductive film 140. Specifically, particles 144a are located between the wire 134a of the COF 130 and the terminal 112a of the TFT substrate 110b. In addition, particles 144a are located between the wire 134b of the COF 130 and the terminal 112b of the TFT substrate 110b. Furthermore, particles 144a are located between the wire 134c of the COF 130 and the terminal 112c of the TFT substrate 110b.

Particles 144b are located in regions, between the wires 134 of the COF 130 (hereinafter also simply referred to as regions between the wires 134 of the COF 130) when viewed in the normal direction of the TFT substrate 110b, in the anisotropic conductive film 140. As described above, the wires 134 of the COF 130 are opposite the corresponding terminals 112 of the TFT substrate 110b, and the pitch and width of the terminals 112 are almost equal to the pitch and width of the wires 134, respectively. It can therefore be said that the particles 144b are located in regions, between the terminals 112 of the TFT substrate 110b (hereinafter also simply referred to as regions between the terminals 112 of the TFT substrate 110b) when viewed in the normal direction of the TFT substrate 110b, in the anisotropic conductive film 140.

Specifically, particles 144b are located in a region between the terminal 112a and the terminal 112b of the TFT substrate 110b (a region between the wire 134a and the wire 134b of the COF 130) when viewed in the normal direction of the TFT substrate 110b. Similarly, particles 144b are located in a region between the terminal 112b and the terminal 112c of the TFT substrate 110b (a region between the wire 134b and the wire 134c of the COF 130) when viewed in the normal direction of the TFT substrate 110b.

In the display panel 100 of the present embodiment, the particles 144a each having at least a surface being conductive are located between the wires 134 of the COF 130 and the terminals 112 of the TFT substrate 110b that are opposite each other. This enables electrical connection between the terminals 112 and the wires 134.

Particles 144b each having at least surface being insulative are located in regions between the terminals 112 of the TFT substrate 110b (regions between the wires 134 of the COF 130). This enables prevention of leaks between the terminals 112, leaks between the wires 134, and leaks between the terminals 112 and the wires 134 that are not opposite each other. For example, particles 144b, being present in a region between the terminal 112a and the terminal 112b of the TFT substrate 110b (a region between the wire 134a and the wire 134b of the COF 130s), in the anisotropic conductive film 140 enables prevention of a leak between the terminal 112a and the terminal 112b, a leak between the wire 134a and the wire 134b, a leak between the terminal 112a and the wire 134b, and a leak between the terminal 112b and the wire 134a. In addition, particles 144, being present in a region between the terminal 112b and the terminal 112c of the TFT substrate 110b (a region between the wire 134b and the wire 134c of the COF 130), in the anisotropic conductive film 140 enable prevention of a leak between the terminal 112b and the terminal 112c, a leak between the wire 134b and the wire 134c, a leak between terminal 112b and the wire 134c, and a leak between terminal 112c and the wire 134b.

Moreover, in the display panel 100 of the present embodiment, the particles 144b are movable relatively freely in the base resin 142. For example, when the COF 130 is pressure-bonded to the TFT substrate 110b, the particles 144b are movable relatively freely in the base resin 142. The anisotropic conductive film 140 therefore enables shortening a distance between the terminals 112 and the wires 134, thickening the other regions, and strong bonding the TFT substrate 110b and the COF 30.

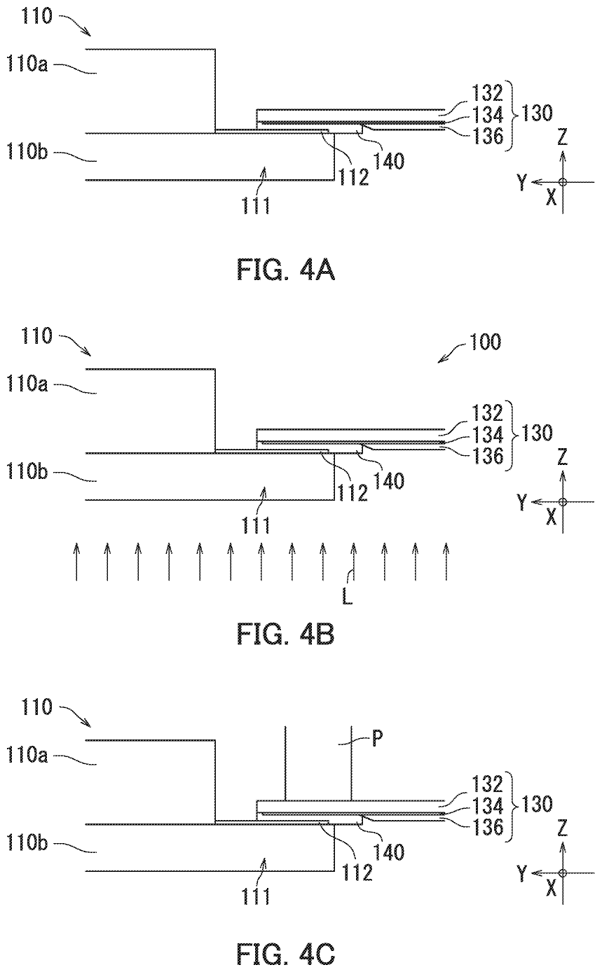

When the display panel 100 of the first embodiment is manufactured, the COFs 130 are pressure-bonded to the TFT substrate 110b of the panel body 110 through the anisotropic conductive films 140. The manufacturing method of the display panel 100, of the first embodiment will hereinafter be described with reference to FIGS. 1 to 4C. Each of FIGS. 4A to 4C is a schematic illustration depicting the manufacturing method of the display panel 100, of the first embodiment.

As illustrated in FIG. 4A, an anisotropic conductive film 140 stuck to a COF 130 is placed on the protruding portion 111 of the TFT substrate 110b of the panel body 110. In this moment, the COF 130 and the anisotropic conductive film 140 are pressure-bonded to the protruding portion 111 of the TFT substrate 110b. Such pressure-bonding is also called temporary pressure-bonding.

The protruding portion 111 of the TFT substrate 110b is provided with the terminals 112. The COF 130 and the anisotropic conductive film 140 are placed on the protruding portion 111 of the TFT substrate 110b, so that the wires 134 of the COF 130 are opposite the corresponding terminals 112 of the TFT substrate 110b through the anisotropic conductive film 140.

Note that the terminals 112 of the TFT substrate 110b and the wires 134 of the COF 130 are preferably made from material that reflects light. For example, at least one of sets that include a set of the terminals 112 of the TFT substrate 110b and a set of the wires 134 of the COF 130 is preferably made from material that reflects light. In particular, the terminals 112 are preferably made from material that reflects light.

For example, the terminals 112 are made from material that reflects ultraviolet light. Alternatively, the terminals 112 are made from material that reflects infrared light. In an example, the terminals 112 are preferably made of metal. Typically, each terminal 112 is a copper wire.

As illustrated in FIG. 4B, light L is directed to the anisotropic conductive film 140. Examples of the light L may include infrared light and ultraviolet light.

For example, the light L is emitted from a back surface of one of the TFT substrate 110b and the COF 130. Here, the light L is emitted from a side of the TFT substrate 110b.

As illustrated in FIG. 4C, pressure is applied to the COF 130 with a pressure member P that is heated, and then the COF 130 is bonded to the TFT substrate 110b. By the pressure member P, the COF 130 and the anisotropic conductive film 140 are more strongly pressure-bonded to the protruding portion 111 of the TFT substrate 110b. Such pressure-bonding is also called main pressure-bonding.

Specifically, with the terminals 112 of the TFT substrate 110b and the wires 134 of the COF 130 overlapped through the anisotropic conductive film 140, the pressure member P applies pressure to the COF 130 toward the TFT substrate 110b side. The pressure member P applies pressure to the COF 130, so that the pressure is applied to the anisotropic conductive film 140 located between the COF 130 and the TFT substrate 110b. Note that the pressure member P may apply pressure to the COF 130 through a buffer member.

For example, the pressure member P in a heated state applies pressure to the COF 130. The pressure member P heats the anisotropic conductive film 140 by applying pressure to the COF 130 toward the TFT substrate 110b. For example, the pressure member P is heated to a temperature of 150° C. or higher and 250° C. or lower. Pressure is applied to the COF 130 with the heated pressure member P, so that the heat of the pressure member P is transferred to the anisotropic conductive film 140 through the COF 130. By the heat of the pressure member P, the COF 130 is pressure-bonded to the TFT substrate 110b. Thus, the anisotropic conductive film 140 bonds the TFT substrate 110b and the COF 130 with the terminals 112 of the TFT substrate 110b and the wires 134 of the COF 130 electrically connected with each other.

As described above, the COF 130 can be pressure-bonded to the protruding portion 111 of the TFT substrate 110b, and thus the display panel 100 can be manufactured.

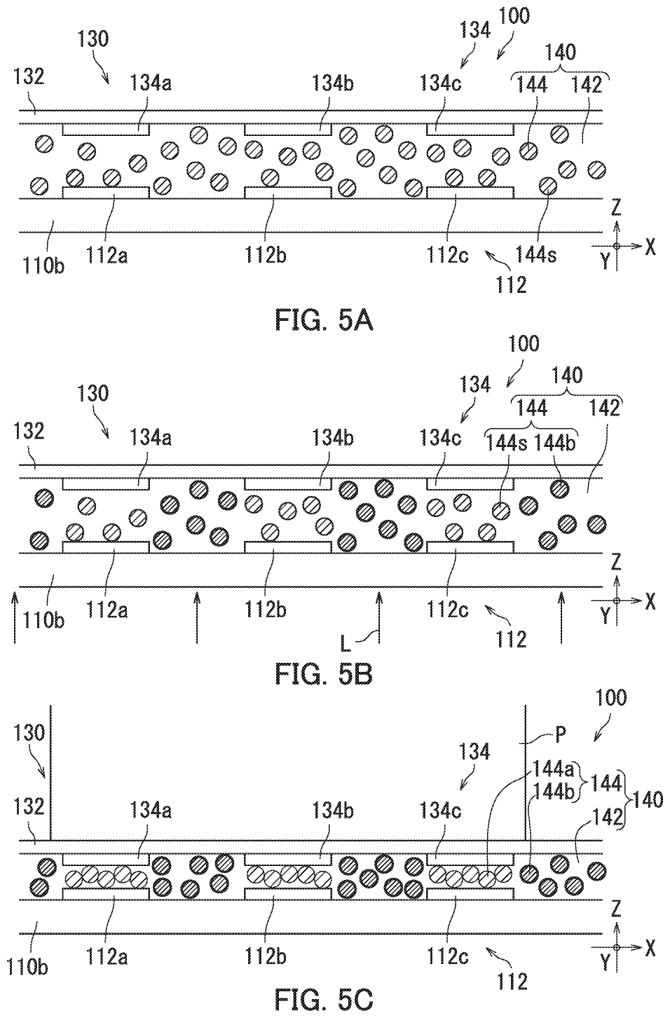

A change of particles in the display panel 100 of the first embodiment will next be described with reference to FIGS. 5A to 5C. Each of FIGS. 5A to 5C is a schematic illustration depicting the layered structure of the TFT substrate 110b, the anisotropic conductive film 140, and the COF 130 in the display panel 100 in the first embodiment. FIGS. 5A to 5C correspond to FIGS. 4A to 4C.

As illustrated in FIG. 5A, when the anisotropic conductive film 140 to which the COF 130 sticks is first placed on the TFT substrate 110b, the anisotropic conductive film 140 is sandwiched between the TFT substrate 110b and the COF 130. At this moment, the terminals 112 of the TFT substrate 110b and the wires 134 of the COF 130 are opposite each other.

The anisotropic conductive film 140 contains the base resin 142 and particles 144. Here, particles 144s as the particles 144 are dispersed in the base resin 142. Note that the particles 144s each have a layered structure. At least each surface of the particles 144s is preferably insulative. For example, the particles 144s each have an insulating layer located on an outer surface thereof and a conductive layer located inside the insulating layer. In the particles 144s, the insulating layer located on each outer surface thereof contains curable resin. Note that in the particle 144s, the insulating layer located on each outer surface thereof may be thinner than the conductive layer so as to allow the insulating layer to be destroyed.

As illustrated in FIG. 5B, light L is directed to the anisotropic conductive film 140. When the light L strikes the anisotropic conductive film 140, the insulating layers of particle 144s, located in regions between the terminals 112 of the TFT substrate 110b, of the particles 144s in the anisotropic conductive film 140 are cured, and the particles 144s located in the regions then change into particles 144b. For example, particle 144s located in a region between the terminal 112a and the terminal 112b of the TFT substrate 110b change into particles 144b, and particle 144s located in a region between the terminal 112b and the terminal 112c of the TFT substrate 110b change into particles 144b.

In contrast, particles 144s, located in regions covered with the terminals 112 of the TFT substrate 110b, namely between the wires 134 of the COF 130 and the terminals 112 of the TFT substrate 110b that are opposite each other, of the particles 144s in the anisotropic conductive film 140 do not change and remain as the particles 144s. The particles 144s located in the regions covered with the terminals 112 of the TFT substrate 110b do not substantially change even if the light L is directed to the anisotropic conductive film 140 because the light does not arrive at the particles 144s located in the regions.

As illustrated in FIG. 5C, by the pressure member P, the COF 130 is pressed to the TFT substrate 110b. When the COF 130 is pressed with the pressure member P, particles 144s, located between the terminals 112 of the TFT substrate 110b and the wires 134 of the COF 130 that are opposite each other, in the anisotropic conductive film 140 change into conductive particles 144a. Specifically, when the COF 130 is pressed, particles 144s located between the terminals 112 of the TFT substrate 110b and the wires 134 of the COF 130 that are opposite each other are sandwiched by the terminals 112 and the wires 134. At this moment, the insulating layers existing on the outer surfaces of the particles 144s are destroyed and the conductive layers are exposed, so that the particles 144s change into the conductive particles 144a. The conductive particles 144a are preferably compressed and elastically deformed by pressure of the pressure member P.

At this moment, surfaces of the particles 144, located in regions between the terminals 112 of the TFT substrate 110b (regions between the wires 134 of the COF 130), of the particles 144 in the anisotropic conductive film 140 have been already cured. In addition, the particles 144b are not sandwiched between the terminals 112 and the wires 134, and force that causes deformation or destruction is not applied to the particles 144b. The particles 144b accordingly remain insulative.

As described above, in the display panel 100, the COF 130 is pressure-bonded to the TFT substrate 110b through the anisotropic conductive film 140. In the display panel 100, the conductive particles 144a are located between the terminals 112 of the TFT substrate 110b and the wires 134 of the COF 130 that are opposite each other. This enables electrical connection between the terminals 112 and the wires 134 that are opposite each other. In addition, insulating particles 144b are located in regions between the terminals 112 of the TFT substrate 110b (regions between the wires 134 of the COF 130). This enables prevention of leaks between the terminals 112, leaks between the wires 134, and leaks between the terminals 112 and the wires 134 that are not opposite each other.

Note that although the light L is emitted from the side of the TFT substrate 110b of the anisotropic conductive film 140 in FIGS. 4B and 5B, the present embodiment is not limited to this. The light L may be emitted from a side of the COF 130 of the anisotropic conductive film 140. Also in this case, when the light L strikes the anisotropic conductive film 140, the insulating layers of the particles 144s, located in the regions between the wires 134 of the COF 130, in the anisotropic conductive film 140 are cured, and the particles 144s change into the particles 144b. In contrast, the particles 144s, located in the regions covered with the wires 134 of the COF 130, namely between the wires 134 of the COF 130 and the terminals 112 of the TFT substrate 110b that are opposite each other, of the particles 144s in the anisotropic conductive film 140 do not change and remains as the particles 144s. It is however preferable that the base substrate 132 of the COF 130 allows the light L to pass therethrough in the case where the light L is emitted from a side of the COF 130 of the anisotropic conductive film 140. For example, the base substrate 132 preferably contains PET resin.

Particles preferably used for the anisotropic conductive films 140 in the display panel 100 of the present embodiment will next be described with reference to FIGS. 1 to 6A.

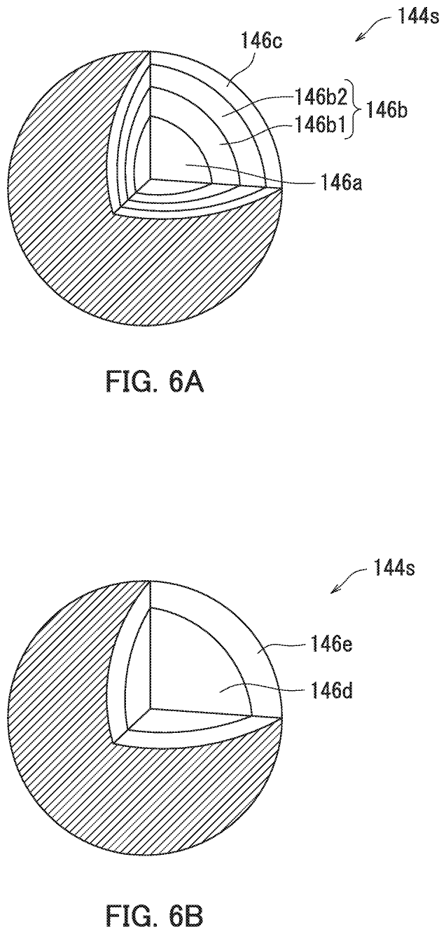

FIG. 6A is a schematic illustration of a particle 144s preferably used for the anisotropic conductive films 140 in the display panel 100 of the present embodiment. Note that in FIG. 6A, the particle 144s is intentionally cut out in order to show an internal structure thereof. The particle 144s has a layered structure. The particle 144s has a core layer 146a, a conductive layer 146b, and an insulating layer 146c.

The core layer 146a is made from insulating material. For example, the core layer 146a may be: any of epoxy resin, phenolic resin, acrylic resin, acrylonitrile and styrene polymer (AS resin), or styrene resin; or a mixture of these. The core layer 146a preferably has a relatively high elasticity. Elasticity of the material of the core layer 146a is preferably higher than elasticity of the material of the conductive layer 146b and/or elasticity of the material of the insulating layer 146c.

The conductive layer 146b is made from conductive material. Note that the conductive layer 146b may have a 2-layer structure. For example, the conductive layer 146b includes a first metal layer 146b1 and a second metal layer 146b2. For example, the first metal layer 146b1 is made of nickel, and the second metal layer 146b2 is made of gold. The first metal layer 146b1 of nickel intervening between the core layer 146a and the second metal layer 146b2 enables the second metal layer 146b2 of gold to be formed on the core layer 146a through the first metal layer 146b1.

The insulating layer 146c contains curable resin. The curable resin of the insulating layer 146c is preferably insulative.

For example, the insulating layer 146c contains photocurable resin. In an example, the insulating layer 146c contains photocurable resin that is cured by ultraviolet light. For example, the insulating layer 146c may contain acrylate-based resin. For example, the acrylate-based resin may be: any of methyl acrylate, ethyl acrylate, or isopropyl acrylate; or a mixture of these.

Alternatively, the insulating layer 146c may contain photocurable resin that is cured by infrared light. Alternatively, the insulating layer 146c may contain thermosetting resin.

Note that when the insulating layer 146c contains photocurable resin, a photopolymerization initiator is preferably added to the insulating layer 146c in addition to curable insulating material. For example, the photopolymerization initiator may be any of benzoin ether based, benzyl ketal based. α-acyloxime ester based, acetophenone based, or ketone based. In an example, the photopolymerization initiator may be benzoin ethyl ether, acetophenone, or benzophenone.

When the insulating layer 146c contains photocurable resin, the insulating layer 146c is preferably transparent. As described above, in FIGS. 4B and 5B, when the insulating layer 146c is cured by the light L incident thereon, the insulating layer 146c being transparent enables the light L incident from one side of the TFT substrate 110b to cure many regions of the insulating layer 146c even if the particles 144 are relatively hard to move and rotate relative to the base resin 142.

The insulating layer 146c is allowed to be destroyed by pressure applied by the pressure member P, and preferably relatively thick. When the insulating layer 146c is cured by the light L incident thereon, the insulating layer 146c being relatively thick enables the light L incident from one side to cure many regions of the insulating layer 146c even if the particles 144 are relatively hard to move and rotate relative to the base resin 142. For example, the insulating layer 146c may be thicker than the conductive layer 146b. Alternatively, the insulating layer 146c may be thicker than one of the first metal layer 146b1 and the second metal layer 146b2.

Note that in the particle 144s of FIG. 6A, the insulating layer, the conductive layer, and the insulating layer are arranged in this order toward the center from the outer surface of the particle 144s. The present embodiment is however not limited to this. In the particle 144s, the insulating layer and the conductive layer may be arranged in this order toward the center from the outer surface of the particle 144s.

A particle preferably used for the anisotropic conductive films 140 in the display panel 100 of the present embodiment will next be described with reference to FIG. 6B.

FIG. 6B is a schematic illustration of a particle 144s preferably used for the anisotropic conductive films 140 in the display panel 100 of the present embodiment. The particle 144s has a layered structure. The particle 144s has a conductive layer 146d and an insulating layer 146e.

The conductive layer 146d is made from conductive material. The conductive layer 146d is preferably made from transparent conductive material. For example, the conductive layer 146d may contain indium tin oxide (ITO), or tin oxide (SnO₂). Alternatively, the conductive layer 146d may contain nano carbon.

The insulating layer 146e contains curable resin. For example, the curable resin may be insulative. For example, the insulating layer 146e contains photocurable resin. In an example, the insulating layer 146e contains photocurable resin that is allowed to be cured by ultraviolet light. Alternatively, the insulating layer 146e contains photocurable resin that is allowed to be cured by infrared light. Alternatively, the insulating layer 146e contains thermosetting resin that is allowed to be cured by heat.

Note that the insulating layer 146e is preferably transparent. As described above, when the insulating layer 146e is cured by the light L incident thereon, the insulating layer 146e being transparent enables the light L incident from one side of the TFT substrate 110b to cure many regions of the insulating layer 146e even if the particles 144 are relatively hard to move and rotate relative to the base resin 142.

The insulating layer 146e may be relatively thick. As described above, when the insulating layer 146e is cured by the light L incident thereon, the insulating layer 146e being relatively thick enables the light L incident from one side of the TFT substrate 110b to cure many regions of the insulating layer 146e even if the particles 144 are relatively hard to move and rotate relative to the base resin 142.

Note that in the above description with reference to FIGS. 4A to 4C and 5A to 5C, the particles 144b are first formed from the particles 144s by the light L incident thereon, and the particles 144a are subsequently formed from the particles 144s by applying pressure to the anisotropic conductive film 140 with the pressure member P. The present embodiment is however not limited to this. The particles 144a may first be formed from the particles 144s by applying pressure to the anisotropic conductive film 140 with the pressure member P. and the particles 144b may subsequently be formed from the particles 144s by the light L incident thereon.

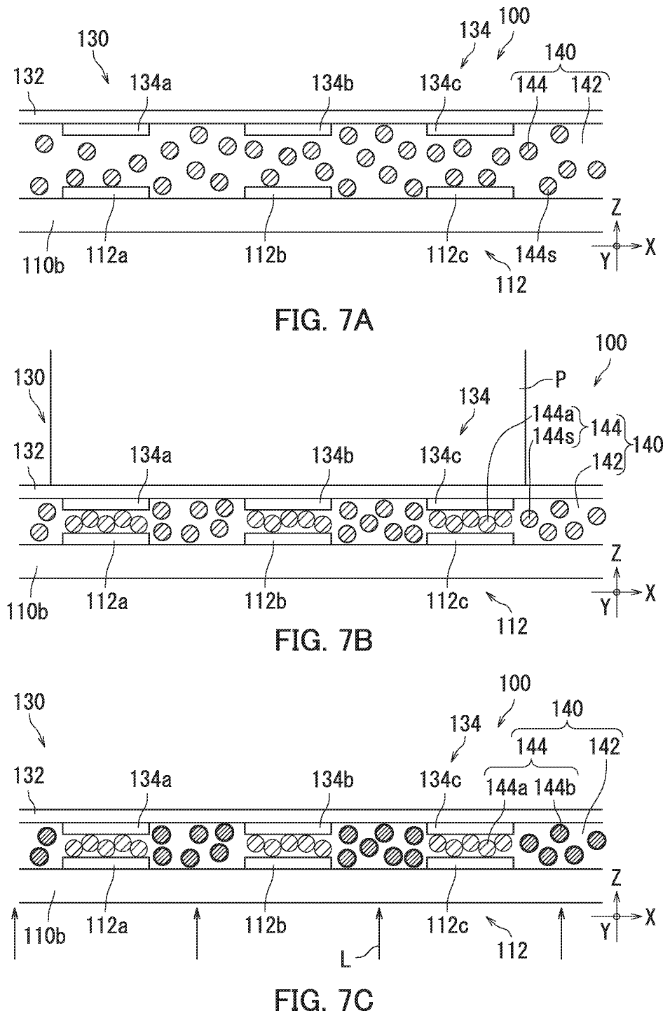

A change of particles 144 in the display panel 100 of the first embodiment will next be described with reference to FIGS. 7A to 7C. Each of FIGS. 7A to 7C is a schematic illustration of the layered structure of the TFT substrate 110b, the anisotropic conductive film 140, and the COF 130 in the display panel 100 of the first embodiment. Note that FIGS. 7A, 7B, and 7C are respectively similar to FIGS. 6A, 6B, and 6C except the order of pressure bonding by the pressure member P and incident light L differ from each other, and duplicate description is omitted in order to avoid redundancy. In addition, FIGS. 7A, 7B, and 7C correspond to FIGS. 4A, 4C, and 4B, respectively.

As illustrated in FIG. 7A, when the anisotropic conductive film 140 to which the COF 130 sticks is placed on the TFT substrate 110b, the TFT substrate 110b is sandwiched between the TFT substrate 110b and the COF 130. At this moment, the terminals 112 of the TFT substrate 110b and the wires 134 of the COF 130 are opposite each other.

As illustrated in FIG. 7B, by the pressure member P, the COF 130 is pressed to the TFT substrate 110b. When the COF 130 is pressed with the pressure member P, particles 144s, located between the terminals 112 of the TFT substrate 110b and the wires 134 of the COF 130 that are opposite each other, in the anisotropic conductive film 140 change into conductive particles 144a. Specifically, when the COF 130 is pressed, the insulating layers existing on the outer surfaces of the particles 144s are destroyed and the conductive layers are exposed, so that the particles 144s change into the conductive particles 144a.

At this moment, pressure by the pressure member P is not substantially applied to particles 144s, located in regions between the terminals 112 of the TFT substrate 110b (regions between the wires 134 of the COF 130), in the anisotropic conductive film 140. The particles 144s accordingly remain insulative.

As illustrated in FIG. 7C, light L is directed to the anisotropic conductive film 140. When the light L strikes the anisotropic conductive film 140, the insulating layers of particles 144s, located in regions between the terminals 112 of the TFT substrate 110b, of the particles 144s in the anisotropic conductive film 140 are cured, and the particles 144s located in the regions change into particles 144b. For example, particles 144s located in the region between the terminal 112a and the terminal 112b of the TFT substrate 110b change into particles 144b, and particles 144s located in the region between the terminal 112b and the terminal 112c of the TFT substrate 110b change into particles 144b.

In contrast, the particles 144a in the anisotropic conductive film 140 are located in regions covered with the terminals 112a of the TFT substrate 110b. Therefore, the particles 144a do not substantially change even if the light L is directed to the anisotropic conductive film 140.

In the display panel 100 of the first embodiment, the conductive particles 144a are located between the terminals 112 of the TFT substrate 110 and the wires 134 of the COF 130 that are opposite each other. This enables electrical connection between the terminals 112 and the wires 134 that are opposite each other. The insulating particles 144b are located in the regions between the terminals 112 of the TFT substrate 110b (regions between the wires 134 of the COF 130). This enables prevention of leaks between the terminals 112, leaks between the wires 134, and leaks between the terminals 112 and the wires 134 that are not opposite each other. As illustrated in FIGS. 7A to 7C, it is possible to form the particles 144a and the particles 144b from the particles 144 in the anisotropic conductive film 140 even if pressure is applied with the pressure member P and the light L is subsequently given.

Note that although pressure is applied with the heated pressure member P in the description with reference to FIGS. 4A to 4C, 5A to 5C, and 7A to 7C, the present embodiment is not limited to this. Pressure may be applied with a non-heated pressure member P.

In addition, although pressure is applied with the heated pressure member P along with the emitted light L in the description with reference to FIGS. 4A to 4C, 5A to 5C, and 7A to 7C, the present embodiment is not limited to this. When the particles 144s in the anisotropic conductive film 140 have an outer surface containing thermosetting resin, the particles 144s may be heated without the light L incident thereon.

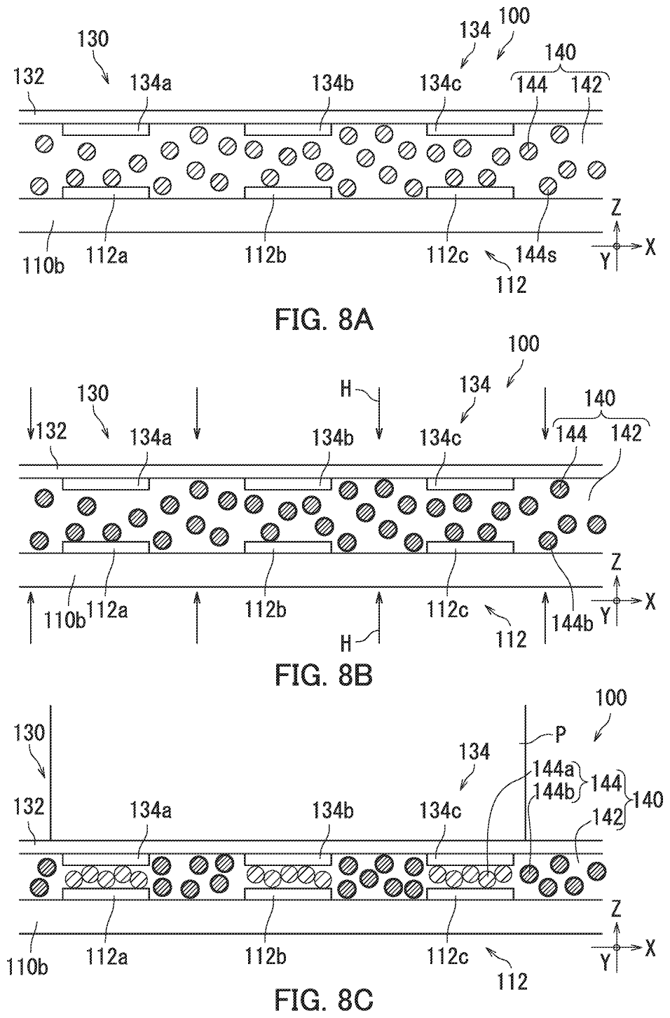

A change of particles in the display panel 100 of the first embodiment will next be described with reference to FIGS. 8A to 8C. Each of FIGS. 8A to 8C is a schematic illustration of the layered structure of the TFT substrate 110b, the anisotropic conductive film 140, and the COF 130 of the display panel 100 in the first embodiment.

As illustrated in FIG. 8A, when the anisotropic conductive film 140 to which the COF 130 sticks is placed on the TFT substrate 110b, the anisotropic conductive film 140 is sandwiched between the TFT substrate 110b and the COF 130. At this moment, the terminals 112 of the TFT substrate 110b and the wires 134 of the COF 130 are opposite each other.

The anisotropic conductive film 140 contains the base resin 142 and particles 144s. The particles 144s are dispersed in the base resin 142. Note that the particles 144s have a layered structure. Here, the particles 144s each have an insulating layer that is located at the outer surface thereof and that contains thermosetting resin.

As illustrated in FIG. 8B, the anisotropic conductive film 140 is heated. Here, the panel body 110, the COF 130, and the anisotropic conductive film 140 are exposed to a heated atmosphere H. When the anisotropic conductive films 140 is heated, the insulating layers of particles 144s, located in the regions between the terminals 112 of the TFT substrate 110b, in the anisotropic conductive film 140 are cured, and the particles 144s located in the regions change into particles 144b. For example, particles 144s located in the region between the terminal 112a and the terminal 112b of the TFT substrate 110b change into particles 144b, and particles 144s located in the region between the terminal 12b and the terminal 112c of the TFT substrate 110b change into particles 144b. Note that in this case, particles 144s located in the region covered with the terminal 112a of the TFT substrate 110b also change into particles 144b in the heated atmosphere H.

As illustrated in FIG. 8C, the COF 130 is pressed to the TFT substrate 110b with the pressure member P. When the COF 130 is pressed with the pressure member P, particles 144b, located between the terminals 112 of the TFT substrate 110b and the wires 134 of the COF 130 that are opposite each other, of the particles 144 in the anisotropic conductive film 140 change into conductive particles 144a. Specifically, when the COF 130 is pressed, particles 144b located between the terminals 112 of the TFT substrate 110b and the wires 134 of the COF 130 that are opposite each other are sandwiched by the terminals 112 and the wires 134. At this moment, the insulating layers existing on the outer surfaces of the particles 144b are destroyed and the conductive layers are exposed, so that the particles 144b change into the conductive particles 144a.

At this moment, force that causes deformation or destruction is not applied to particles 144b, located in regions between the terminals 112 of the TFT substrate 110b (regions between the wires 134 of the COF 130), in the anisotropic conductive film 140 because the particles 144b are not sandwiched between the terminals 112 and the wires 134. The particles 144b therefore remain insulative.

As described above, in the display panel 100, the COF 130 is pressure-bonded to the TFT substrate 110b through the anisotropic conductive film 140. In the display panel 100, conductive particles 144a are located between the terminals 112 of the TFT substrate 110b and the wires 134 of the COF 130 that are opposite each other. This enables electrical connection between the terminals 112 and the wires 134 that are opposite each other. In addition, insulating particles 144b are located in the regions between the terminals 112 of the TFT substrate 110b (regions between the wires 134 of the COF 130). This enables prevention of the leaks between the terminals 112, the leaks between the wires 134, and the leaks between the terminals 112 and the wires 134 that are not opposite each other.

Note that in the above description with reference to FIGS. 8A to 8C, the anisotropic conductive film 140 is first heated in the heated atmosphere H to form the particles 144b from the particles 144s, and pressure is subsequently applied to the anisotropic conductive film 140 to form the particles 144a from the particles 144b. The present embodiment is however not limited to this. Pressure may first be applied to the anisotropic conductive film 140 to form the particles 144a from the particles 144s, and the anisotropic conductive film 140 may subsequently be heated under the heated atmosphere H to form the particles 144b from the particles 144s.

Although heating the anisotropic conductive film 140, and applying pressure to the anisotropic conductive film 140 with the pressure member P are performed separately in the above description with reference to FIGS. 8A to 8C, the present embodiment is not limited to this. Heating the anisotropic conductive film 140, and applying pressure to the anisotropic conductive film 140 with the pressure member P may be performed at the same time. For example, heat and pressure may be applied to the anisotropic conductive film 140 by applying pressure to the anisotropic conductive film 140 with the pressure member P heated without exposing the anisotropic conductive film 140 to the heated atmosphere H.

Note that although the conductive particles 144a and the insulating particles 144b are dispersed in the base resin 142 of the anisotropic conductive film 140 in the above description with reference to FIGS. 3 to 8C, the present embodiment is not limited to this. Different types of conductive particles and different types of insulating particles may be dispersed in the base resin 142 of the anisotropic conductive film 140.

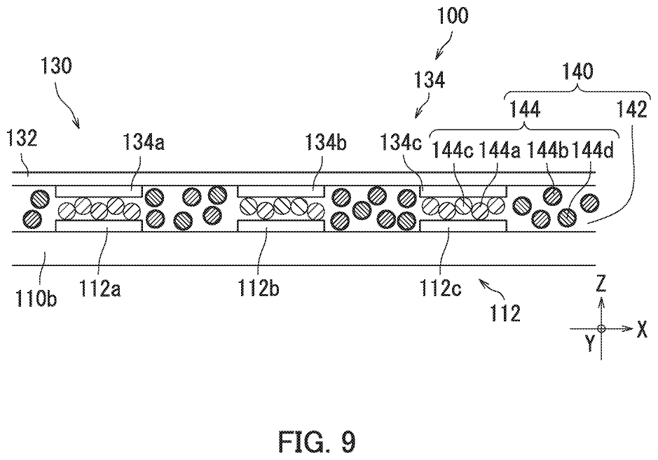

A display panel 100 of a second embodiment will next be described with reference to FIG. 9. FIG. 9 is a schematic illustration depicting a structure, in the vicinity of a COF 130, of the display panel 100 of the second embodiment. FIG. 9 is similar to FIG. 3 except particles 144c and particles 144d in addition to particles 144a and particles 144b are dispersed in base resin 142 of an anisotropic conductive film 140.

As illustrated in FIG. 9, the anisotropic conductive film 140 has the base resin 142, the particles 144a, the particles 144b, the particles 144c, and the particles 144d. At least each surface of the particles 144a and the particles 144c is conductive, and at least each surface of the particles 144b and the particles 144d is insulative.

The particles 144c are particles different in type from the particles 144a. Note that density (weight per unit volume) and/or particle size of the particles 144c is preferably different from density and/or particle size of the particles 144a. Typically, although the particles in the anisotropic conductive film 140 are uniformly dispersed in the base resin 142, the particles may be non-uniformly dispersed in the base resin 142 when some force is applied to the anisotropic conductive film 140. Nonuniformity of the particles varies according to the density and/or the particle size of the particles. The particles 144a and the particles 144c being different from each other in density and/or particle size therefore enables conductive particles to be prevented from being lost between the terminals 112 and the wires 134 even if some force is applied to the anisotropic conductive film 140 when the COF 130 and the anisotropic conductive film 140 are pressure-bonded to the TFT substrate 110b.

Similarly, the particles 144d are particles different in type from the particles 144b. Density and/or particle size of the particles 144d is preferably different from density and/or particle size of the particles 144b. The particles 144b and the particles 144d being different from each other in density and/or particle size enables insulating particles to be prevented from being lost between the terminals 112 and the wires 134 even if some force is applied to the anisotropic conductive film 140 when the COF 130 and the anisotropic conductive film 140 are pressure-bonded to the TFT substrate 110b.

The particles 144a and the particles 144b may be formed from the same particles. For example, the particles 144a and the particles 144b may be formed from particles 144s as illustrated in FIG. 6A.

The particles 144c and the particles 144d may be formed from the same particles. For example, the particles 144c and the particles 144d may be formed from particles 144s as illustrated in FIG. 6B.

Typically, when density of original particles of the particles 144a and the particles 144b differs from density of original particles of the particles 144c and the particles 144d, density of the particles 144a differs from density of the particles 144c, and density of the particles 144b differs from density of particles 144d.

Note that although the particles 144 dispersed in the base resin 142 of the anisotropic conductive film 140 each have a conductive layer, the present embodiment is not limited to this. Particles each having no conductive layer may be mixed in the base resin 142 of the anisotropic conductive film 140.

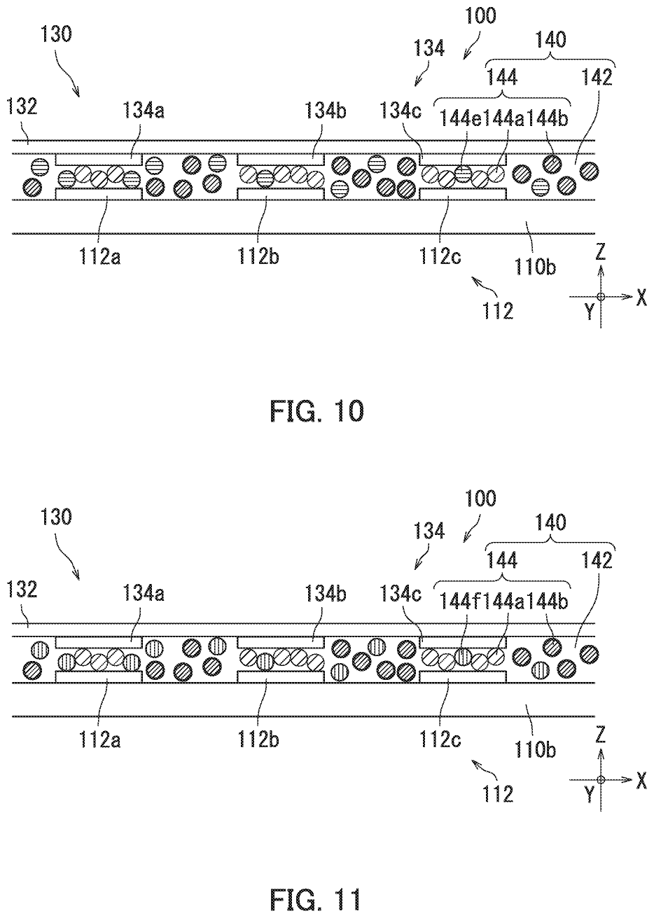

A display panel 100 of a third embodiment will next be described with reference to FIG. 10. FIG. 10 is a schematic illustration depicting a structure, in the vicinity of a COF 130, of the display panel 100 of the third embodiment. FIG. 10 is similar to FIG. 3 except particles 144e in addition to particles 144a and particles 144b are dispersed in base resin 142 of an anisotropic conductive film 140. Duplicate description is omitted in order to avoid redundancy.

As illustrated in FIG. 10, the anisotropic conductive film 140 contains the base resin 142, the particles 144a, the particles 144b, and the particles 144e. At least each surface of the particles 144a is conductive, at least each surface of the particles 144b is insulative, and the particles 144e are each insulative as a whole.

The particles 144a and the particles 144b are formed from the same particles. For example, the particles 144a and the particles 144b are formed from particles 144s as illustrated in FIG. 6A or 6B.

The particles 144e are made from insulating resin. Note that the particles 144e may each have a surface that is further coated with insulating material.

In the display panel 100 of the present embodiment, the anisotropic conductive film 140 contains insulating particles 144e in addition to the particles 144a and the particles 144b. This enables increase in the number of insulating particles, located in regions between terminals 112 of a TFT substrate 110b (regions between wires 134 of the COF 130), in the anisotropic conductive film 140, and prevention of leaks between the terminals 112, leaks between the wires 134, and leaks between the terminals 112 and the wires 134 that are not opposite each other. However, the number of particles 144e per unit volume in the anisotropic conductive film 140 is preferably smaller than the number of particles 144a and particles 144b per unit volume.

Note that although all the particles dispersed in the base resin 142 of the anisotropic conductive film 140 have an insulating component in the above description with reference to FIG. 10, the present embodiment is not limited to this. Particles having no insulating component may be mixed in the base resin 142 of the anisotropic conductive film 140.

A display panel 100 of a fourth embodiment will next be described with reference to FIG. 11. FIG. 11 is a schematic illustration depicting a structure, in the vicinity of a COF 130, of the display panel 100 of the fourth embodiment. FIG. 11 is similar to FIG. 3 except particles 144f in addition to particles 144a and particles 144b are dispersed in base resin 142 of an anisotropic conductive film 140. Duplicate description is omitted in order to avoid redundancy.

As illustrated in FIG. 11, the anisotropic conductive film 140 contains the base resin 142, the particles 144a, the particles 144b, and the particles 144f. At least each surface of the particles 144a is conductive, the particles 144f are each conductive as a whole, and at least each surface of the particles 144b is insulative.

As described above, particles 144a are located between wires 134 of the COF 130 and terminals 112c of a TFT substrate 110b that are opposite each other. In addition, particles 144b are located in regions between the wires 134 of the COF 130 (regions between the terminals 112 of the TFT substrate 110b). The particles 144a and the particles 144b are formed from the same particles. For example, the particles 144a and the particles 144b are formed from particles as illustrated in FIG. 6A or 6B.

The particles 144f are formed from conductive material. Note that the particles 144f may be metal particles. Alternatively, the particles 144f may contain nano carbon.

In the display panel 100 of the present embodiment, the anisotropic conductive film 140 contains conductive particles 144f in addition to the particles 144a and the particles 144b. This enables further increase in the number of particles, located between the terminals 112 of the TFT substrate 110b and the wires 134 of the COF 130 that are opposite each other, in the anisotropic conductive film 140, and further improvement in electrical connection between the terminals 112 and the wires 134 that are opposite each other. However, the number of particles 144f per unit volume in the anisotropic conductive film 140 is preferably smaller than the number of particles 144a and particles 144b per unit volume.

As above, the embodiments have been described with reference to the drawings. However, the present disclosure is not limited to the above-described embodiments and can be practiced in various ways within the scope without departing from the essence of the present disclosure. Constituent elements disclosed in the above embodiments can be combined as appropriate in various different disclosures to form various inventions. For example, some constituent elements may be omitted from all of the constituent elements described in the embodiments. The drawings mainly illustrate schematic constituent elements in order to facilitate understanding of the disclosure, and numbers or the like of each constituent element illustrated in the drawings may differ from actual ones thereof in order to facilitate preparation of the drawings. Furthermore, configurations of the elements of configuration described in the above embodiments are merely examples and are not intended as specific limitations. Various alterations may be made so long as there is no substantial deviation from the effects of the present disclosure.

For example, although a liquid-crystal display panel is illustrated as the panel body 110 in the above description with reference to FIGS. 1 to 11, the present disclosure is not limited to this. The panel body 110 may be an organic electroluminescent (EL) display panel.

The present application further discloses appendixes below. Note that the appendixes below do not limit the present disclosure.

### APPENDIX 1

A manufacturing method of a display panel including: a first panel substrate; a second panel substrate that is opposite the first panel substrate and that has a protruding portion that protrudes from the first panel substrate; and a wiring board connected to the protruding portion of the second panel substrate, the method including:

overlapping protruding terminals and wiring terminals with the protruding terminals and the wiring terminals being opposite each other through an anisotropic conductive film, the protruding terminals being provided at the protruding portion, the wiring terminals being placed on one surface of the wiring board, the anisotropic conductive film containing particles having a conductive layer and a curable resin layer covering a surface of the conductive layer;

exposing the conductive layer on a surface of particles, located between the protruding terminals of the second panel substrate and the wiring terminals of the wiring board that are opposite each other, of the particles in the anisotropic conductive film; and

curing the curable resin layer of particles, located in regions between the protruding terminals of the second panel substrate or regions between the wiring terminals of the wiring board when viewed in a normal direction of the second panel substrate, of the particles in the anisotropic conductive film.

### APPENDIX 2

The manufacturing method of the display panel, according to appendix 1, wherein

the curing includes emitting light from a back surface of one of the second panel substrate and the wiring board.

### APPENDIX 3

The manufacturing method of the display panel, according to appendix 2, wherein

the emitting the light includes emitting ultraviolet light.

### APPENDIX 4

A manufacturing method of the display panel, according to any of appendixes 1 to 3, wherein

the curing includes heating the anisotropic conductive film.

### APPENDIX 5

A manufacturing method of the display panel, according to any of appendixes 1 to 4, wherein

the exposing the conductive layer includes applying pressure to the anisotropic conductive film located between the second panel substrate and the wiring board.

### APPENDIX 6

A manufacturing method of the display panel, according to any of appendixes 1 to 5, wherein

the particles further have a core layer covered with the conductive layer.

### APPENDIX 7

A display panel comprising:

a first panel substrate;

a second panel substrate that is opposite the first panel substrate;

a wiring board; and

an anisotropic conductive film, wherein

the second panel substrate has a protruding portion that protrudes from the first panel substrate,

the wiring board is connected to the protruding portion of the second panel substrate,

protruding terminals are provided at the protruding portion,

the wiring board has one surface on which the wiring terminals are placed,

the protruding terminals of the protruding portion in the second panel substrate and the wiring terminals on the one surface of the wiring board are overlapped through the anisotropic conductive film with the protruding terminals and the wiring terminals being opposite each other,

the anisotropic conductive film contains base resin and particles dispersed in the base resin,

the particles have a conductive layer, and a curable resin layer covering the conductive layer,

particles, located between the protruding terminals of the second panel substrate and the wiring terminals of the wiring board that are opposite each other, of the particles in the anisotropic conductive film have a surface formed as a result of the conductive layer being exposed, and

the curable resin layer of particles, located in regions between the protruding terminals of the second panel substrate or regions between the wiring terminals of the wiring board when viewed in a normal direction of the second panel substrate, of the particles in the anisotropic conductive film is cured.

1. A manufacturing method of a display panel including: a first panel substrate; a second panel substrate that is opposite the first panel substrate and that has a protruding portion that protrudes from the first panel substrate; and a wiring board connected to the protruding portion of the second panel substrate, the method comprising:
overlapping protruding terminals and wiring terminals with the protruding terminals and the wiring terminals being opposite each other through an anisotropic conductive film, the protruding terminals being provided at the protruding portion, the wiring terminals being placed on one surface of the wiring board, the anisotropic conductive film containing particles having a conductive layer and a curable resin layer covering a surface of the conductive layer,
exposing the conductive layer on a surface of particles, located between the protruding terminals of the second panel substrate and the wiring terminals of the wiring board that are opposite each other, of the particles in the anisotropic conductive film; and
curing the curable resin layer of particles, located in regions between the protruding terminals of the second panel substrate or regions between the wiring terminals of the wiring board when viewed in a normal direction of the second panel substrate, of the particles in the anisotropic conductive film.

2. The manufacturing method of the display panel, according to claim 1, wherein
the curing includes emitting light from a back surface of one of the second panel substrate and the wiring board.

3. The manufacturing method of the display panel, according to claim 2, wherein
the emitting the light includes emitting ultraviolet light.

4. The manufacturing method of the display panel, according to claim 1, wherein
the curing includes heating the anisotropic conductive film.

5. The manufacturing method of the display panel, according to claim 1, wherein
the exposing the conductive layer includes applying pressure to the anisotropic conductive film located between the second panel substrate and the wiring board.

6. The manufacturing method of the display panel, according to claim 1, wherein
the particles further have a core layer covered with the conductive layer.

7. A display panel comprising:
a first panel substrate;
a second panel substrate that is opposite the first panel substrate;
a wiring board; and
an anisotropic conductive film, wherein
the second panel substrate has a protruding portion that protrudes from the first panel substrate,
the wiring board is connected to the protruding portion of the second panel substrate,
protruding terminals are provided at the protruding portion,
the wiring board has one surface on which the wiring terminals are placed,
the protruding terminals of the protruding portion in the second panel substrate and the wiring terminals on the one surface of the wiring board are overlapped through the anisotropic conductive film with the protruding terminals and the wiring terminals being opposite each other,
the anisotropic conductive film contains base resin and particles dispersed in the base resin,
the particles have a conductive layer, and a curable resin layer covering the conductive layer,
particles, located between the protruding terminals of the second panel substrate and the wiring terminals of the wiring board that are opposite each other, of the particles in the anisotropic conductive film have a surface formed as a result of the conductive layer being exposed, and
the curable resin layer of particles, located in regions between the protruding terminals of the second panel substrate or regions between the wiring terminals of the wiring board when viewed in a normal direction of the second panel substrate, of the particles in the anisotropic conductive film is cured.
